(19) United States
(12) Patent Application Publication
(10) Pub. No.: US 2026/0198293 A1
(43) Pub. Date: Jul. 9, 2026

(54) SEMICONDUCTOR DEVICE

(71) Applicant: SAMSUNG ELECTRONICS CO., LTD., Suwon-si (KR)

(72) Inventors: Yuji MOON, Suwon-si (KR); Gukhee KIM, Suwon-si (KR); Jeongwoong SHIN, Suwon-si (KR); Ra YOU, Suwon-si (KR); Minseung LEE, Suwon-si (KR); Seungseok HA, HA (KR); Junsun HWANG, Suwon-si (KR)

(73) Assignee: SAMSUNG ELECTRONICS CO., LTD., Suwon-si (KR)

(21) Appl. No.: 19/259,832

(22) Filed: Jul. 3, 2025

(30) Foreign Application Priority Data
Jan. 7, 2025 (KR) 10-2025-0002087

(51) Int. Cl. H01L 23/528; H10D 84/83

(52) U.S. Cl. CPC H10W 20/43; H10D 84/832

(57) ABSTRACT

A semiconductor device includes a transistor, a first element spaced apart from the transistor in a first direction, a backside insulating structure below the transistor and the first element in a second direction that is perpendicular to the first direction, a passivation structure between the first element and the backside insulating structure, and a backside conductive pattern in the backside insulating structure and connected to the passivation structure, where the first element includes a first semiconductor region having a first conductivity type and a second semiconductor region having a second conductivity type and that forms a PN junction with the first semiconductor region, the passivation structure includes a first insulating passivation layer contacting a lower surface of the first element and a conductive passivation layer below the first insulating passivation layer, and the backside conductive pattern is connected to the conductive passivation layer.

### CROSS-REFERENCE TO RELATED APPLICATION(S)

This application is based on and claims priority to Korean Patent Application No. 10-2025-0002087, filed on Jan. 7, 2025, in the Korean Intellectual Property Office, the disclosure of which is incorporated by reference herein in its entirety.

### BACKGROUND

The present disclosure relates to a semiconductor device and a method of manufacturing the same.

As demand for high performance, high speed, and/or multifunctionality of semiconductor devices increases, the integration of semiconductor devices is increasing. To manufacture semiconductor devices with fine patterns corresponding to the trend toward high integration of semiconductor devices, implementing patterns having fine widths or fine gaps may be required. In addition, efforts are being made to develop semiconductor devices including fin field effect transistors (FinFETs) having a three-dimensional channel structure to reduce limitations of operating characteristics due to the reduction in the size of planar metal oxide semiconductor FETs (MOSFETs).

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device in which integration may be increased and performance may be improved, and a method of manufacturing the same.

Additional aspects will be set forth in part in the description which follows and, in part, will be apparent from the description, or may be learned by practice of the presented embodiments.

According to an aspect of one or more embodiments, a semiconductor device may include a transistor, a first element spaced apart from the transistor in a first direction, a backside insulating structure below the transistor and the first element in a second direction that is perpendicular to the first direction, a passivation structure between the first element and the backside insulating structure, and a backside conductive pattern disposed in the backside insulating structure and connected to the passivation structure, where the first element includes a first semiconductor region having a first conductivity type and a second semiconductor region having a second conductivity type and that forms a PN junction with the first semiconductor region, the passivation structure includes a first insulating passivation layer contacting a lower surface of the first element and a conductive passivation layer below the first insulating passivation layer, and the backside conductive pattern is connected to the conductive passivation layer.

According to an aspect of one or more embodiments, a semiconductor device may include a transistor, a first element spaced apart from the transistor in a first direction, the first element including a semiconductor body including a first semiconductor region having a P-type conductivity type and a second semiconductor region having an N-type conductivity type, a backside insulating structure below the transistor and the first element in a second direction that is perpendicular to the first direction, a passivation structure between the first element and the backside insulating structure, and a backside conductive pattern disposed in the backside insulating structure and connected to the passivation structure, where the passivation structure includes a first insulating passivation layer contacting the semiconductor body and a conductive passivation layer below the first insulating passivation layer in the second direction, and where the backside conductive pattern is connected to the conductive passivation layer and is spaced apart from the first semiconductor region and the second semiconductor region in the second direction.

According to an aspect of one or more embodiments, a semiconductor device may include a transistor, a first element spaced apart from the transistor in a first direction, a backside insulating structure below the transistor and the first element in a second direction that is perpendicular to the first direction, a conductive passivation layer between the first element and the backside insulating structure and not between the transistor and the backside insulating structure, an insulating passivation layer between the first element and the conductive passivation layer, and a backside conductive pattern connected to the conductive passivation layer, where the first element includes a first semiconductor region and a second semiconductor region that forms a PN junction, and the conductive passivation layer includes doped polysilicon.

According to an aspect of one or more embodiments, a method of manufacturing a semiconductor device may include forming a structure including a transistor and a first element, forming a passivation structure that covers a backside surface of the first element, forming a first backside interlayer insulating layer covering the passivation structure, and forming a backside conductive pattern that penetrates the first backside interlayer insulating layer, where the backside conductive pattern is connected to the passivation structure. The method may also include forming a semiconductor body with an exposed lower surface by forming a frontside insulating structure and reducing a thickness of a semiconductor wafer to expose a lower surface of a semiconductor body. The method may also include forming a first insulating passivation layer contacting a lower surface of the first semiconductor body, forming a conductive passivation layer contacting the first insulating passivation layer, and forming a second insulating passivation layer contacting the conductive passivation layer.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a semiconductor device according to one or more embodiments;

FIG. 2A is a plan view illustrating a portion of a first element area of a semiconductor device according to one or more embodiments;

FIG. 2B is a plan view illustrating some components of FIG. 2A according to one or more embodiments;

FIG. 3A is a cross-sectional view illustrating a region taken along line Ia-Ia′ of FIG. 2A according to one or more embodiments;

FIG. 3B is a cross-sectional view illustrating regions taken along lines IIa-IIa′ and IIIa-IIIa′ of FIG. 2A according to one or more embodiments;

FIG. 3C is an enlarged view illustrating region ‘A’ of FIG. 3A according to one or more embodiments;

FIG. 4 is a plan view illustrating a portion of a transistor area of a semiconductor device according to one or more embodiments;

FIG. 5A is a cross-sectional view illustrating regions taken along lines IVa-IVa′ and IVb-IVb′ of FIG. 4 according to one or more embodiments;

FIG. 5B is a cross-sectional view illustrating areas taken along lines V-V′, VI-VI′, and VII-VII′ of FIG. 4 according to one or more embodiments;

FIG. 6 is a cross-sectional view illustrating a semiconductor device according to one or more embodiments;

FIG. 7 is a cross-sectional view illustrating a semiconductor device according to one or more embodiments;

FIG. 8 is a cross-sectional view illustrating a semiconductor device according to one or more embodiments; and

FIG. 9, FIG. 10A, FIG. 10B, and FIG. 10C are diagrams illustrating a method of manufacturing a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

Unless otherwise specifically stated, in this specification, terms such as “upper,” “upper surface,” “lower,” “lower surface,” “side surface,” and the like are based on the drawings and may vary depending on the direction in which the components are disposed.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In addition, ordinal numbers such as “first,” “second,” “third,” and the like may be used as labels for specific elements, steps, directions, and the like to distinguish various elements, steps, directions, and the like. Terms that are not described using “first,” “second,” or the like in the specification may still be referred to as “first” or “second” in the claims. In addition, terms that are referenced by a specific ordinal number (for example, “first” in a specific claim) may be described elsewhere with a different ordinal number (for example, “second” in the specification or another claim).

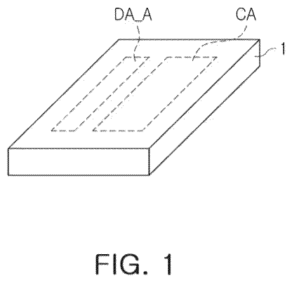

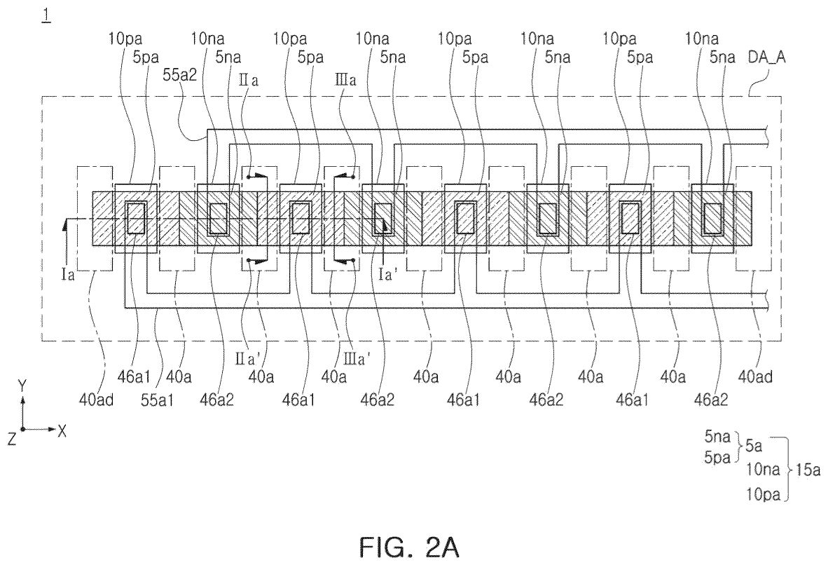

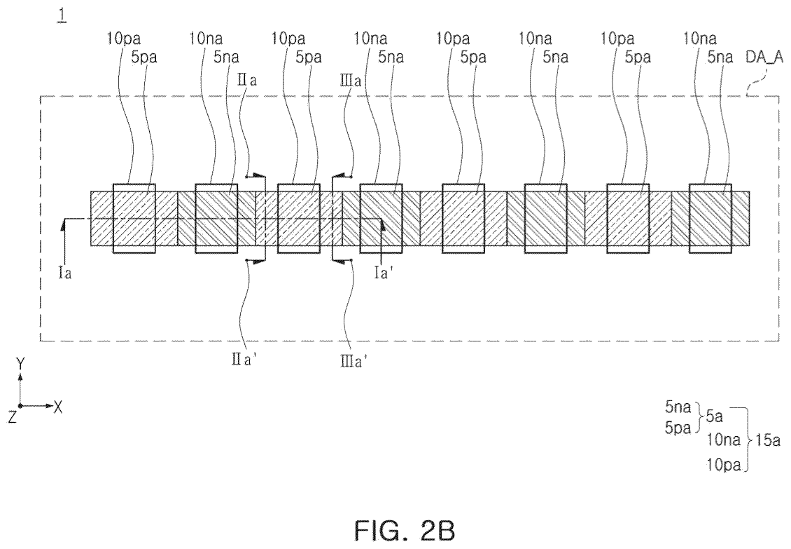

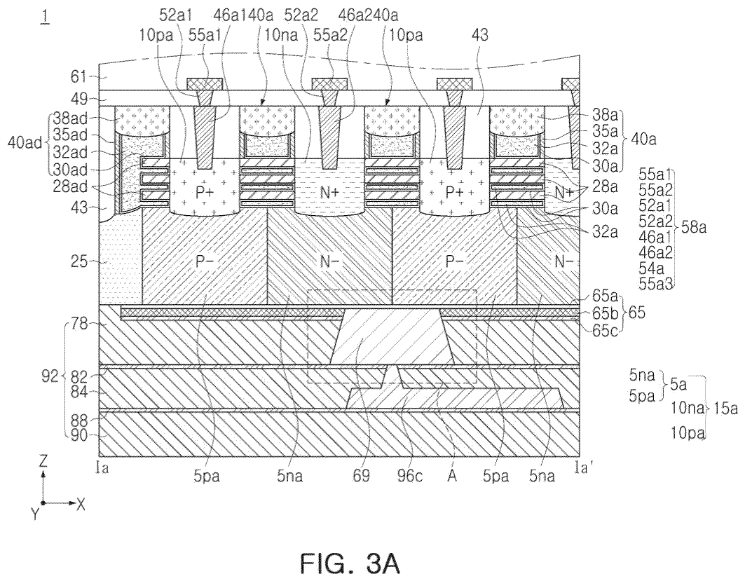

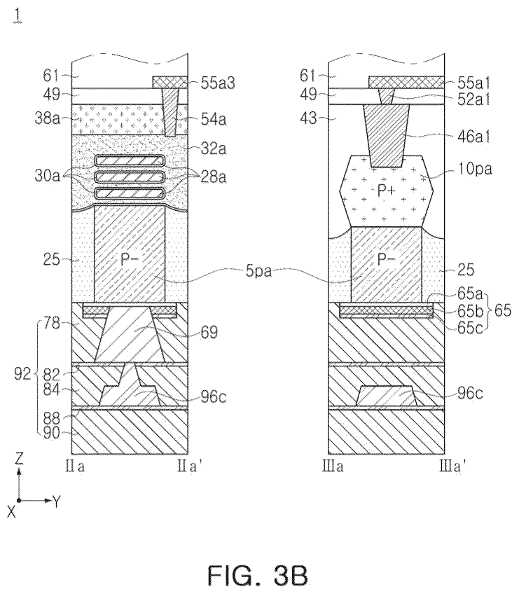

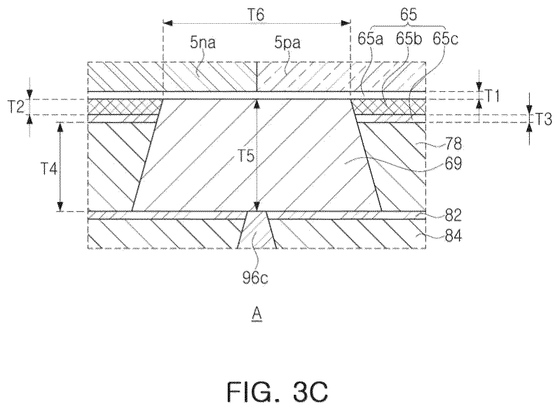

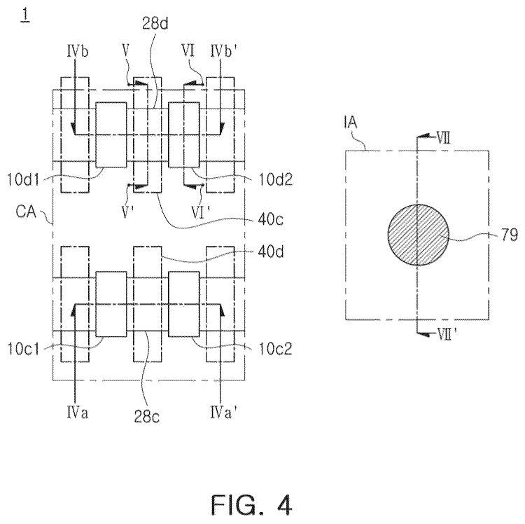

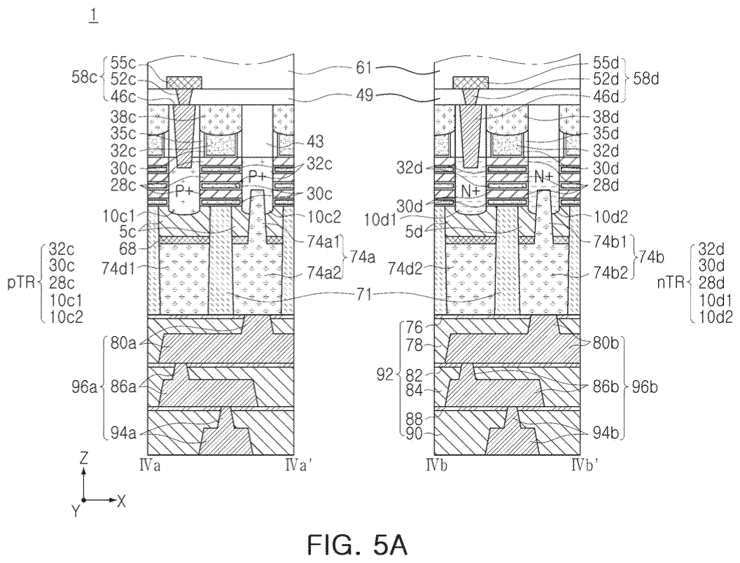

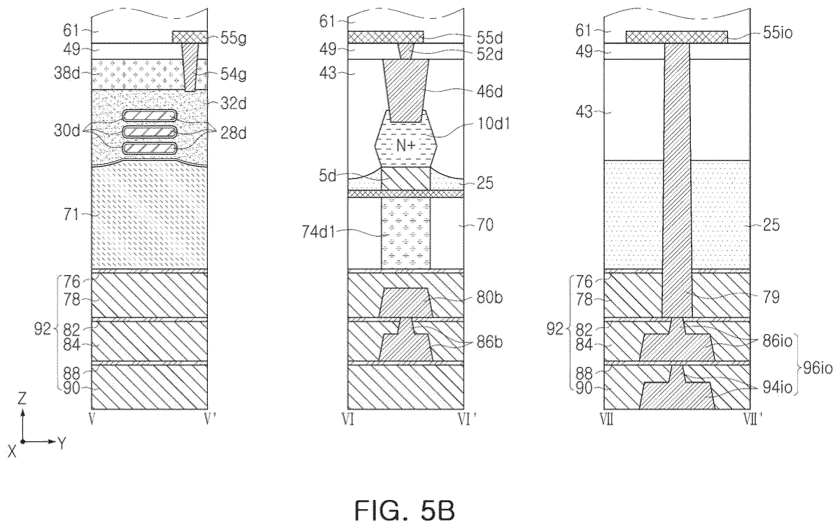

FIG. 1 is a diagram illustrating a semiconductor device 1 according to one or more embodiments, FIG. 2A is a plan view illustrating a portion of a first element area DA_A of a semiconductor device 1 according to one or more embodiments, FIG. 2B is a plan view illustrating some components of FIG. 2A according to one or more embodiments, FIG. 3A is a cross-sectional view illustrating a region taken along line Ia-Ia′ of FIG. 2A according to one or more embodiments, FIG. 3B is a cross-sectional view illustrating regions taken along lines IIa-IIa′ and IIIa-IIIa′ of FIG. 2A according to one or more embodiments, FIG. 3C is an enlarged view illustrating region ‘A’ of FIG. 3A according to one or more embodiments, FIG. 4 is a plan view illustrating a portion of a transistor area CA of a semiconductor device 1 according to one or more embodiments, FIG. 5A is a cross-sectional view illustrating regions taken along lines IVa-IVa′ and IVb-IVb′ of FIG. 4 according to one or more embodiments, and FIG. 5B is a cross-sectional view illustrating regions taken along lines V-V′, VI-VI′, and VII-VII′ of FIG. 4 according to one or more embodiments.

First, referring to FIG. 1, a semiconductor device 1 according to one or more embodiments may include a first element area DA_A and a transistor area CA.

The first element area DA_A may be a region including elements using a PN junction. For example, the first element area DA_A may include at least one of a first diode of a Lateral PN (LPN) type in which a side surface of a P-type semiconductor region and a side surface of an N-type semiconductor region are joined, a second diode of a vertical PN (VPN) type in which a P-type semiconductor region and an N-type semiconductor region are joined in a vertical direction, PNP Bipolar Junction Transistor (PNP BJT) elements, and NPN BJT elements.

The transistor area CA may be a region including transistors such as a metal oxide semiconductor (MOS) field effect transistor (FET) (MOSFET) including a source, a drain, a channel region, and a gate. For example, the transistor area CA may include a transistor having a Multi Bridge Channel FET (MBCFET™) structure, a gate-all-around field effect transistor (GAAFET), etc. The semiconductor device 1 may further include a connection area (not illustrated) for routing input/output signals. The transistor area CA may include a frontside conductive structure disposed on the transistors and a backside interconnection structure disposed below the transistors.

Next, referring to FIG. 1, FIG. 2A, FIG. 2B, FIG. 3A, FIG. 3B, and FIG. 3C, an example of the first element area DA_A of the semiconductor device 1 will be described.

Referring to FIG. 1, FIG. 2A, FIG. 2B, FIG. 3A, and FIG. 3B, the first element area DA_A of the semiconductor device 1 may include a first element 15a.

The first element 15a may include a first semiconductor body 5a, a first semiconductor pattern 10pa, and a second semiconductor pattern 10na.

The first semiconductor body 5a may be formed of a semiconductor material. For example, the first semiconductor body 5a may include at least one of silicon (Si), silicon germanium (SiGe), germanium (Ge), and silicon carbide (SiC). For example, the first semiconductor body 5a may include single crystal silicon.

The first semiconductor body 5a may include a first semiconductor region 5pa having a first conductivity type and a second semiconductor region 5na having a second conductivity type and forming a PN junction with the first semiconductor region 5pa. The first semiconductor body 5a may have a thickness of about 50 nm to about 60 nm in a vertical direction (e.g., the Z direction). That is, at least one of the first semiconductor region 5pa and the second semiconductor region 5na of the first element 15a may have a thickness of about 50 nm to about 60 nm in the vertical direction (e.g., the Z direction).

In one or more embodiments, one of the first conductive type and the second conductive type may be a P-type conductive type, and the other may be an N-type conductive type. For example, the first conductive type may be a P-type conductive type, and the second conductive type may be an N-type conductive type. In another example, the first conductive type may be an N-type conductive type, and the second conductive type may be a P-type conductive type.

The first semiconductor pattern 10pa may be connected to the first semiconductor region 5pa on the first semiconductor region 5pa, and the second semiconductor pattern 10na may be connected to the second semiconductor region 5na on the second semiconductor region 5na.

In one or more embodiments, the first semiconductor region 5pa may be disposed in multiple numbers (i.e., a plurality of first semiconductor regions may be provided), the second semiconductor region 5na may be disposed in multiple numbers (i.e., a plurality of second semiconductor regions may be provided), the first semiconductor pattern 10pa may be disposed in multiple numbers (i.e., a plurality of first semiconductor patterns may be provided), and the second semiconductor pattern 10na may be disposed in multiple numbers (i.e., a plurality of second semiconductor patterns may be provided).

The first semiconductor body 5a may have a bar shape extending in the first direction (e.g., the X direction). The first semiconductor regions 5pa and the second semiconductor regions 5na may be arranged alternately in the first direction (e.g., the X direction).

The first semiconductor patterns 10pa may be disposed on the first semiconductor regions 5pa of the first semiconductor body 5a and may have the first conductivity type. One first semiconductor pattern of the first semiconductor patterns 10pa may be disposed on a first semiconductor region of one of the first semiconductor regions 5pa. The width of each of the first semiconductor patterns 10pa in the first direction (e.g., the X direction) may be smaller than the width of each of the first semiconductor regions 5pa in the first direction (e.g., the X direction). The first semiconductor patterns 10pa and the first semiconductor regions 5pa may have the same conductivity type, for example, a P-type conductivity type. The first semiconductor patterns 10pa and the first semiconductor regions 5pa may be doped with impurities such as a Group 13 element of the Periodic Table, for example, B or Al. The impurity concentration of the first semiconductor patterns 10pa may be higher than the impurity concentration of the first semiconductor regions 5pa. The first semiconductor patterns 10pa may be formed as an epitaxial layer epitaxially grown from the first semiconductor body 5a. Each of the first semiconductor patterns 10pa may include at least one of silicon, silicon germanium, and germanium.

The second semiconductor patterns 10na may be disposed on the second semiconductor regions 5na of the first semiconductor body 5a and may have the second conductivity type. One second semiconductor pattern of the second semiconductor patterns 10na may be disposed on one second semiconductor region of the second semiconductor regions 5na. The width of each of the second semiconductor patterns 10na in the first direction (e.g., the X direction) may be smaller than the width of each of the second semiconductor regions 5na in the first direction (e.g., the X direction). The second semiconductor patterns 10na and the second semiconductor regions 5na may have the same conductivity type, for example, an N-type conductivity type. The second semiconductor patterns 10na and the second semiconductor regions 5na may be doped with impurities, such as a Group 15 element of the periodic table, for example, P or As. The impurity concentration of the second semiconductor patterns 10na may be higher than the impurity concentration of the second semiconductor regions 5na. The second semiconductor patterns 10na may be formed as an epitaxial layer epitaxially grown from the first semiconductor body 5a. Each of the second semiconductor patterns 10na may include silicon.

In one or more embodiments, the first semiconductor patterns 10pa may include silicon germanium, and the second semiconductor patterns 10na may not include silicon germanium.

Throughout the drawing, a region indicated as “N−”may be an N-type low-concentration semiconductor region having an N-type conductivity and a relatively low impurity concentration, a region indicated as “P−”may be a P-type low-concentration semiconductor region having a P-type conductivity and a relatively low impurity concentration, a region indicated as “N+” may be an N-type high-concentration semiconductor region having a N-type conductivity and a relatively high impurity concentration, and a region indicated as “P+” may be a P-type high-concentration semiconductor region having a P-type conductivity and a relatively high impurity concentration. In this case, the low-concentration semiconductor region and the high-concentration semiconductor region may be defined by the relative impurity concentrations in semiconductor regions having the same conductivity.

The first element area DA_A of the semiconductor device 1 may further include first dummy active structures 28a and 28ad. The first dummy active structures 28a and 28ad may include first edge dummy active structures 28ad and first dummy active structures 28a between the first edge dummy active structures 28ad. Each of the first edge dummy active structures 28ad may include first edge dummy active layers spaced apart from each other in the vertical direction (e.g., the Z direction). Each of the first dummy active structures 28a may include first dummy active layers spaced apart from each other in the vertical direction (e.g., the Z direction). The first edge dummy active layers and the first dummy active layers of the first dummy active structures 28a and 28ad may be formed of a semiconductor material. For example, the first edge dummy active layers and the first dummy active layers of the first dummy active structures 28a and 28ad may include at least one of silicon, silicon germanium, germanium, and silicon carbide.

The first and second semiconductor patterns 10pa and 10na may be respectively disposed between adjacent dummy active structures 28a and 28ad among the dummy active structures 28a and 28ad. The first dummy active structures 28a may be disposed between adjacent semiconductor patterns among the first and second semiconductor patterns 10pa and 10na. The dummy active structures 28a and 28ad may be connected to the first and second semiconductor patterns 10pa and 10na.

The first element area DA_A of the semiconductor device 1 may further include an element isolation layer 25 on the side surface of the first semiconductor body 5a. The element isolation layer 25 may surround the side surface of the first semiconductor body 5a. The element isolation layer 25 may be formed of an insulating material.

The first element area DA_A of the semiconductor device 1 may further include first gate structures 40a and 40ad.

The first gate structures 40a and 40ad may include first edge gate structures 40ad and first gate structures 40a disposed between the first edge gate structures 40ad. The first edge gate structures 40ad may be respectively disposed on the first semiconductor body 5a and the element isolation layer 25.

The first edge gate structures 40ad may include a portion that overlaps the first edge dummy active structures 28ad. Each of the first edge gate structures 40ad may include a gate electrode 32ad surrounding the first edge active layers of the first edge dummy active structure 28ad, an insulating spacer 35ad on a side surface of the gate electrode 32ad, a gate dielectric layer 30ad disposed between the gate electrode 32ad and the first edge active layers of the first edge dummy active structure 28ad, covering a lower surface of the gate electrode 32ad, and disposed between the gate electrode 32ad and the insulating spacer 35ad, and an insulating capping pattern 38ad on the gate electrode 32ad.

The first gate structures 40a may be vertically above the first dummy active structures 28a. Each of the first gate structures 40a may include a gate electrode 32a surrounding the first dummy active layers of the first dummy active structure 28a, an insulating spacer 35a on a side surface of the gate electrode 32a, a gate dielectric layer 30a disposed between the gate electrode 32a and the first dummy active layers of the first dummy active structure 28a, covering a lower surface of the gate electrode 32a, and disposed between the gate electrode 32a and the insulating spacer 35a, and an insulating capping pattern 38a on the gate electrode 32a.

The first gate structures 40a may be disposed on PN junction regions between the first semiconductor regions 5pa and the second semiconductor regions 5na.

When the first element 15a is in operation or when the first element 15a is turned off, a voltage that may suppress or prevent leakage current from flowing to the first dummy active layers of the first dummy active structures 28a disposed between the first and second semiconductor patterns 10pa and 10na may be applied to the gate electrodes 32a of the first gate structures 40 a. For example, approximately 0 V may be applied to the gate electrodes 32a of the first gate structures 40a. Accordingly, the first gate structures 40a may improve the performance of the first element 15a.

The first element area DA_A of the semiconductor device 1 may further include a first interlayer insulating layer 43 disposed on the first and second semiconductor patterns 10pa and 10na and the element isolation layer 25 and disposed on side surfaces of the first gate structures 40a and 40ad, a second interlayer insulating layer 49 disposed on the first gate structures 40a and 40ad and the first interlayer insulating layer 43, and a frontside insulating structure 61 on the second interlayer insulating layer 49.

The first element area DA_A of the semiconductor device 1 may further include a first frontside conductive structure 58a.

The first frontside conductive structure 58a may include first lower contact plugs 46a1 penetrating the first interlayer insulating layer 43 and electrically connected to the first semiconductor patterns 10pa, and second lower contact plugs 46a2 penetrating the first interlayer insulating layer 43 and electrically connected to the second semiconductor patterns 10na.

The first frontside conductive structure 58a may include first upper contact plugs 52a1 penetrating the second interlayer insulating layer 49 and electrically connected to the first lower contact plugs 46a1, and second upper contact plugs 52a2 penetrating the second interlayer insulating layer 49 and electrically connected to the second lower contact plugs 46a2.

The first frontside conductive structure 58a may further include a gate contact plug 54a that penetrates the second interlayer insulating layer 49 and the insulating capping pattern 38a and is electrically connected to the gate electrode 32a.

The first frontside conductive structure 58a may further include, on the second interlayer insulating layer 49, a first interconnection 55a1 that is electrically connected to the first upper contact plugs 52a1, a second interconnection 55a2 that is electrically connected to the second upper contact plugs 52a2, and a gate interconnection 55a3 that is electrically connected to the gate contact plug 54a.

The frontside insulating structure 61 may cover the first interconnection 55a1, the second interconnection 55a2, and the gate interconnection 55a3.

In one or more embodiments, the first interconnection 55a1 and the second interconnection 55a2 may be disposed so that the first element 15a forms a PN diode as in FIG. 2A. However, embodiments are not limited thereto. For example, the first and second interconnections 55a1 and 55a2 may be modified in various forms so that the first element 15a forms a PNP BJT element or an NPN BJT element. Accordingly, the first element 15a may be configured as a PN diode, a PNP BJT element, or an NPN BJT element depending on the form of the first frontside conductive structure 58a.

The first element area DA_A of the semiconductor device 1 may further include a backside insulating structure 92 disposed below the first element 15a, and a passivation structure 65 disposed between the backside insulating structure 92 and the first element 15a.

The backside insulating structure 92 may include a first backside interlayer insulating layer 78, a second backside etch stop layer 82, a second backside interlayer insulating layer 84, a third backside etch stop layer 88, and a third backside interlayer insulating layer 90 that are sequentially disposed in a direction away from the passivation structure 65.

The first to third backside interlayer insulating layers 78, 84 and 90 may include silicon oxide or a low-k dielectric having a dielectric constant lower than that of silicon oxide. The second and third backside etch stop layers 82, 88 may include a material other than silicon oxide or a low-k dielectric. For example, the second and third backside etch stop layers 82, 88 may include an insulating material such as SiN, SiBN, SiCN, or AlN. Referring to FIG. 3C, the vertical length T4 of the first backside interlayer insulating layer 78 may be in a range of about 5 nm to about 15 nm.

The passivation structure 65 may include a first insulating passivation layer 65a contacting the lower surface of the first semiconductor body 5a, a conductive passivation layer 65b disposed below the first insulating passivation layer 65a, and a second insulating passivation layer 65c disposed between the first backside interlayer insulating layer 78 and the conductive passivation layer 65b.

Referring to FIG. 3C, the thickness T1 of the first insulating passivation layer 65a may be in a range of about 0.5 nm to about 1.5 nm, the thickness T2 of the conductive passivation layer 65b may be in a range of about 4.5 nm to about 5.5 nm, and the thickness T3 of the second insulating passivation layer 65c may be in a range of about 2.5 nm to about 3.5 nm. The thickness of the passivation structure 65 may be in a range of about 8.5 nm to about 11.5 nm. The conductive passivation layer 65 b may have a thickness greater than the thickness T1 of the first insulating passivation layer 65a.

The first insulating passivation layer 65a may include silicon oxide, silicon nitride, and/or silicon oxynitride. The first insulating passivation layer 65a may contact at least one of the first semiconductor region 5pa and the second semiconductor region 5na.

The conductive passivation layer 65b may include a semiconductor material or a conductive material. In one or more embodiments, the conductive passivation layer 65b may include doped poly silicon, and in particular, the conductive passivation layer 65b may include boron-doped poly silicon.

The second insulating passivation layer 65c may include a material other than silicon oxide or a low-k dielectric. For example, the second insulating passivation layer 65c may include an insulating material such as SiN, SiBN, SiCN, or AlN.

The first element area DA_A of the semiconductor device 1 may further include a backside conductive pattern 69 embedded (e.g., provided) in the backside insulating structure 92 and connected to the passivation structure 65.

Referring to FIG. 3C, the backside conductive pattern 69 may include a conductive material such as copper (Cu), tungsten (W), or molybdenum (Mo).

The backside conductive pattern 69 may penetrate the second insulating passivation layer 65c and contact the conductive passivation layer 65b. A portion of the side surface of the backside conductive pattern 69 may contact the side surface of the conductive passivation layer 65b and the side surface of the second insulating passivation layer 65c. In one or more embodiments, the upper surface of the backside conductive pattern 69 may be coplanar or substantially coplanar with the upper surface of the conductive passivation layer 65b.

The backside conductive pattern 69 may be connected to the conductive passivation layer 65b and spaced apart from the first and second semiconductor regions 5pa and 5na. The upper surface of the backside conductive pattern 69 may contact the first insulating passivation layer 65a. The upper surface of the backside conductive pattern 69 may contact a portion of the lower surface of the first insulating passivation layer 65a. The lower surface of the backside conductive pattern 69 and the lower surface of the first backside interlayer insulating layer 78 may be coplanar or substantially coplanar.

The passivation structure 65 may not overlap the transistor area CA in the vertical direction, and in particular, the conductive passivation layer 65b may not overlap the transistor area CA in the vertical direction.

The backside conductive pattern 69 may have a length T5 in the vertical direction of about 15 nm to about 25 nm, and the width T6 of the backside conductive pattern 69 may be in the range of about 45 nm to about 55 nm. The aspect ratio of the backside conductive pattern 69 may be in the range of about 0.3 to about 0.6.

The first element area DA_A of the semiconductor device 1 may further include a first element area backside interconnection structure 96c embedded (e.g., provided) in the backside insulating structure 92 and electrically connected to the backside conductive pattern 69. The first element area backside interconnection structure 96c is electrically connected to the backside conductive pattern 69 and may penetrate the second backside etch stop layer 82 and the second backside interlayer insulating layer 84.

By applying a negative voltage to the conductive passivation layer 65b through the backside conductive pattern 69, surface defects, such as dangling bonds, of the lower surface of the first semiconductor body 5a may be reduced. Accordingly, the performance of the first element 15a may be improved.

The negative charge in the conductive passivation layer 65b generated by applying a negative voltage to the conductive passivation layer 65b through the backside conductive pattern 69 may affect the charge distribution near the lower surface of the first semiconductor body 5a, thereby controlling the surface charge density at the lower surface of the first semiconductor body 5a. That is, the conductive passivation layer 65b may reduce the recombination probability between electrons and holes at the lower surface of the first semiconductor body 5a. Therefore, the passivation structure 65 including the first insulating passivation layer 65a and the conductive passivation layer 65b may prevent or reduce leakage current due to the Generation-Recombination Current (G-R current) that may occur at the lower surface of the first semiconductor body 5a of the first element 15a. Therefore, the passivation structure 65 may improve the performance of the first element 15a.

Next, with reference to FIGS. 1 to 3B, FIG. 4, FIG. 5A, and FIG. 5B, one or more embodiments of the transistor area CA of the semiconductor device 1 will be described.

Referring to FIGS. 4, 5A, and 5B, the transistor area CA of the semiconductor device 1 may include a first transistor pTR and a second transistor nTR. The first transistor pTR may be a p-type MOS (PMOS) transistor, and the second transistor nTR may be an n-type MOS (NMOS) transistor.

The first transistor pTR may include first source/drain patterns 10c1 and second source/drain patterns 10c2 spaced apart from each other, first active layers 28c disposed between the first source/drain patterns 10c1 and the second source/drain patterns 10c2 and spaced apart from each other in the vertical direction (e.g., the Z direction), gate electrodes 32c respectively surrounding the first active layers 28c, and gate dielectric layers 30c between the gate electrodes 32c and the first active layers 28c. The gate dielectric layers 30c may cover a lower surface and a side surface of the gate electrode 32c. The first active layers 28c may be channel layers. The first active layers 28c may include at least one of a semiconductor material, for example, silicon, silicon germanium, germanium, and silicon carbide. The first source/drain pattern 10c1 and the second source/drain pattern 10c2 may be formed of a semiconductor material having a P-type conductivity. The first source/drain pattern 10c1 and the second source/drain pattern 10c2 may include the same semiconductor material as the first semiconductor patterns 10pa described above. For example, the first source/drain pattern 10c1 and the second source/drain pattern 10c2 may include epitaxial silicon germanium.

The second transistor nTR may include a third source/drain pattern 10d1 and a fourth source/drain pattern 10d2 spaced apart from each other, second active layers 28d disposed between the third source/drain pattern 10d1 and the fourth source/drain pattern 10d2 and spaced apart from each other in the vertical direction (e.g., the Z direction), a gate electrode 32d surrounding each of the second active layers 28d, and a gate dielectric layer 30d between the gate electrode 32d and the second active layers 28d. The gate dielectric layer 30d may cover a lower surface and a side surface of the gate electrode 32d. The second active layers 28d may be channel layers. The second active layers 28d may include at least one of a semiconductor material, for example, silicon, silicon germanium, germanium, and silicon carbide. The third source/drain pattern 10d1 and the fourth source/drain pattern 10d2 may be formed of a semiconductor material having an N-type conductivity. The third source/drain pattern 10d1 and the fourth source/drain pattern 10d2 may include the same semiconductor material as the second semiconductor patterns 10na described above. For example, the third source/drain pattern 10d1 and the fourth source/drain pattern 10d2 may include epitaxial silicon and may not include epitaxial silicon germanium.

The first and second active layers 28c and 28d and the dummy active layers of the first and second dummy active structures 28a described above may be disposed at the same level.

At least a portion of at least one of the first to fourth source/drain patterns 10c1, 10c2, 10d1 and 10d2 may be disposed at the same level as at least a portion of at least one of the first and second semiconductor patterns 10pa and 10na.

The transistor area CA of the semiconductor device 1 may further include an insulating spacer 35c on the side surface of the gate electrode 32c of the first transistor pTR and an insulating capping pattern 38c on the gate electrode 32c, and may further include an insulating spacer 35d on the side surface of the gate electrode 32d of the second transistor nTR and an insulating capping pattern 38d on the gate electrode 32d.

The transistor area CA of the semiconductor device 1 may further include a first semiconductor layer 5c under the first transistor nTR and a second semiconductor layer 5d under the second transistor pTR. The first and second semiconductor layers 5c and 5d may be formed of the same semiconductor material as the first semiconductor body 5a.

The first semiconductor body 5a may be disposed at the same level and may have the same thickness. The first and second semiconductor layers 5c and 5d may be disposed at the same level and may have the same or substantially the same thickness. The thickness of the first semiconductor body 5a may be greater than the thickness of each of the first and second semiconductor layers 5c and 5d. The lower surface of the first semiconductor body 5a may be disposed at a lower level than the lower surfaces of the first and second semiconductor layers 5c and 5d.

In one or more embodiments, the passivation structure 65 may not be disposed below the first and second transistors pTR and nTR.

The transistor area CA of the semiconductor device 1 may further include the element isolation layer 25, the first interlayer insulating layer 43, the second interlayer insulating layer 49, and the frontside insulating structure 61.

The element isolation layer 25 may be disposed on the side surfaces of the first and second semiconductor layers 5c and 5d. The first interlayer insulating layer 43 may be disposed on the element isolation layer 25 and the first to fourth source/drain patterns 10c1, 10c2, 10d1 and 10d2. The second interlayer insulating layer 49 may be disposed on the first interlayer insulating layer 43 and the insulating capping patterns 38c and 38d, and the frontside insulating structure 61 may be disposed on the second interlayer insulating layer 49.

The transistor area CA of the semiconductor device 1 may further include a third frontside conductive structure 58c and a fourth frontside conductive structure 58d.

The third frontside conductive structure 58c may include a first lower contact plug 46c penetrating the first interlayer insulating layer 43 and electrically connected to the first source/drain pattern 10c1, a first upper contact plug 52c penetrating the second interlayer insulating layer 49 and electrically connected to the first lower contact plug 46c, and a first gate interconnection 55c electrically connected to the first upper contact plug 52c on the second interlayer insulating layer 49.

The fourth frontside conductive structure 58d may include a second lower contact plug 46d penetrating the first interlayer insulating layer 43 and electrically connected to the third source/drain pattern 10d1, a second upper contact plug 52d penetrating the second interlayer insulating layer 49 and electrically connected to the second lower contact plug 46d, and a second gate interconnection 55d electrically connected to the second upper contact plug 52d on the second interlayer insulating layer 49.

The transistor area CA of the semiconductor device 1 may further include a gate contact plug 54g penetrating the second interlayer insulating layer 49 and the insulating capping pattern 38d and electrically connected to the gate electrode 32d, and a gate interconnection 55g electrically connected to the gate contact plug 54g on the second interlayer insulating layer 49.

The transistor area CA of the semiconductor device 1 may further include the backside insulating structure 92. The backside insulating structure 92 may be disposed below the first and second transistors pTR and nTR and the element isolation layer 25.

The backside insulating structure 92 may be disposed at the same level within the transistor area CA and the first element area DA_A.

The transistor area CA of the semiconductor device 1 may include a first backside conductive pattern 74a disposed between the backside insulating structure 92 and the first transistor pTR and a second backside conductive pattern 74b disposed between the backside insulating structure 92 and the second transistor nTR.

The transistor area CA of the semiconductor device 1 may further include a buffer insulating layer 68 disposed below the lower surfaces of the first and second semiconductor layers 5c and 5d.

The first backside conductive pattern 74a may include a first portion 74a2 disposed below the buffer insulating layer 68, and a second portion 74a1 extending upward from the first portion 74a2 and penetrating through the buffer insulating layer 68 and the first semiconductor layer 5c and electrically connected to the second source/drain pattern 10c2. The first backside conductive pattern 74a may be a first backside source/drain contact plug.

The second backside conductive pattern 74b may include a first portion 74b2 disposed below the buffer insulating layer 68, and a second portion 74b1 extending upward from the first portion 74b2 and penetrating through the buffer insulating layer 68 and the second semiconductor layer 5d and electrically connected to the fourth source/drain pattern 10d2. The second backside conductive pattern 74b may be a second backside source/drain contact plug.

The transistor area CA of the semiconductor device 1 may further include a first dummy conductive pattern 74d1 disposed below the buffer insulating layer 68 with the first source/drain pattern 10c1 being vertically above the first dummy conductive pattern 74d1, and a second dummy conductive pattern 74d2 disposed below the buffer insulating layer 68 with the third source/drain pattern 10d1 being vertically above the second dummy conductive pattern 74d2.

The first and second backside conductive patterns 74a and 74b and the first and second dummy conductive patterns 74d1, 74d2 may have lower surfaces that form a common plane.

In one or more embodiments, the lower surface of the first semiconductor body 5a may be disposed at a level lower than the center between respective upper and lower surfaces of the first and second backside conductive patterns 74a and 74b.

Portions of the first and second backside conductive patterns 74a and 74b may be disposed at the same level as respective portions of each of the first semiconductor body 5a.

The transistor area CA of the semiconductor device 1 may further include insulating isolation structures 71 and an insulating layer 70. The insulating isolation structure 71 may extend through (e.g., downwardly through in the Z direction) the first and second semiconductor layers 5c and 5d and the buffer insulating layer 68 disposed below the gate electrodes 32c and 32d, and the insulating layer 70 may be disposed on side surfaces of the insulating isolation structures 71 under the buffer insulating layer 68. The first backside conductive pattern 74a and the first dummy conductive pattern 74d1 may be spaced apart from each other by the insulating isolation structure 71, and the second backside conductive pattern 74b and the first dummy conductive pattern 74d1 may be spaced apart from each other by the insulating isolation structure 71.

The transistor area CA of the semiconductor device 1 may further include backside interconnection structures 96a and 96b embedded in the backside insulating structure 92 and electrically connected to the first and second backside conductive patterns 74a and 74b.

The backside interconnection structures 96a and 96b may include a first backside interconnection structure 96a electrically connected to the first backside conductive pattern 74a and a second backside interconnection structure 96b electrically connected to the second backside conductive pattern 74b.

The first backside interconnection structure 96a may be electrically connected to the first backside conductive pattern 74a and may include a first-first backside interconnection structure 80a penetrating the first backside etch stop layer 76 and the first backside interlayer insulating layer 78, a first-second backside interconnection structure 86a penetrating the second backside etch stop layer 82 and the second backside interlayer insulating layer 84, and a first-third backside interconnection structure 94a penetrating the third backside etch stop layer 88 and the third backside interlayer insulating layer 90. The second backside interconnection structure 96b may be electrically connected to the second backside conductive pattern 74b and may include a second-first backside interconnection structure 80b penetrating the first backside etch stop layer 76 and the first backside interlayer insulating layer 78, a second-second backside interconnection structure 86b penetrating the second backside etch stop layer 82 and the second backside interlayer insulating layer 84, and a second-third backside interconnection structure 94b penetrating the third backside etch stop layer 88 and the third backside interlayer insulating layer 90.

The connection area CA of the semiconductor device 1 may include a frontside input/output interconnection structure 55io, a backside input/output interconnection structure 96io, and a connection contact structure 79 electrically connecting the frontside input/output interconnection structure 55io and the backside input/output interconnection structure 96io between the frontside input/output interconnection structure 55io and the backside input/output interconnection structure 96io. The frontside input/output interconnection structure 55io may be disposed on the second interlayer insulating layer 49. The backside input/output interconnection structure 96io may be embedded within at least a portion of the backside insulating structure 92. For example, the backside input/output interconnection structure 96io may include a first backside input/output interconnection structure 86io penetrating the second backside etch stop layer 82 and the second backside interlayer insulating layer 84, and a second backside input/output interconnection structure 94io penetrating the third backside etch stop layer 88 and the third backside interlayer insulating layer 90. The connection contact structure 79 may penetrating the element isolation layer 25, the first and second interlayer insulating layers 43 and 49, and a portion of the backside insulating structure 92.

The backside interconnection structures 96a, 96b and 96io, the backside conductive patterns 74a and 74b, and the connection contact structure 79 may be used as paths for input/output signals, power voltages, and ground voltages.

Next, various modified examples of the components of the above-described embodiments will be described. The various modified examples of the components of the above-described embodiments described below will be described with a focus on the modified or replaced components. In this case, the previously described components may be directly cited without a separate detailed description, or the description may be omitted. In addition, the modified or replaced components described below are described with reference to the drawings below, but the modified or replaced components may be combined with each other or with the previously described components to form a semiconductor device according to one or more embodiments.

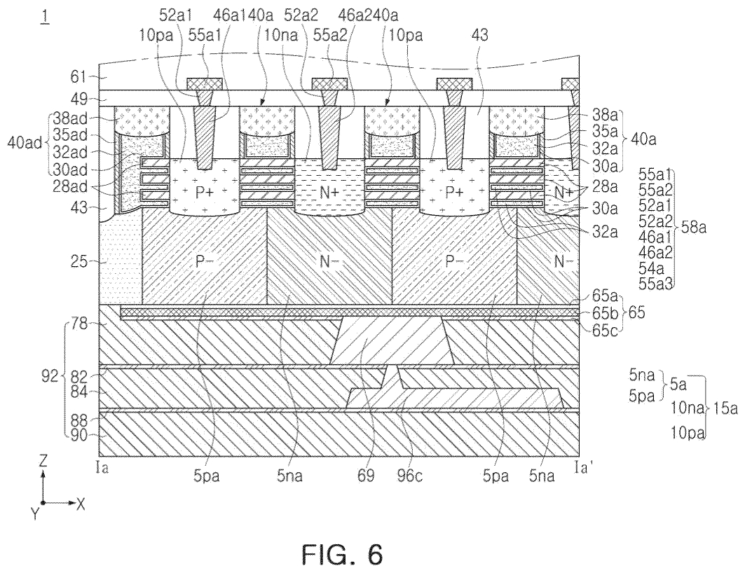

FIG. 6 is a cross-sectional view illustrating a semiconductor device according to one or more embodiments. FIG. 6 illustrates an area corresponding to an area taken along line Ia-Ia′ of FIG. 2A.

Referring to FIG. 6, the backside conductive pattern in FIG. 3A (69 of FIG. 3A) may be replaced with a backside conductive pattern 69 that penetrates the second insulating passivation layer 65c and contacts the lower surface of the conductive passivation layer 65b.

The backside conductive pattern 69 may be electrically connected to the conductive passivation layer 65b by penetrating the second insulating passivation layer 65c. The upper surface of the backside conductive pattern 69 may contact a portion of the lower surface of the conductive passivation layer 65b. In addition, the backside conductive pattern 69 may contact the side surface of the second insulating passivation layer 65c. In one or more embodiments, the upper surface of the backside conductive pattern 69 may be coplanar or substantially coplanar with the lower surface of the conductive passivation layer 65b.

The backside conductive pattern 69 may contact the conductive passivation layer 65b and spaced apart from the first insulating passivation layer 65a. The lower surface of the backside conductive pattern 69 and the lower surface of the first backside interlayer insulating layer 78 may be coplanar or substantially coplanar.

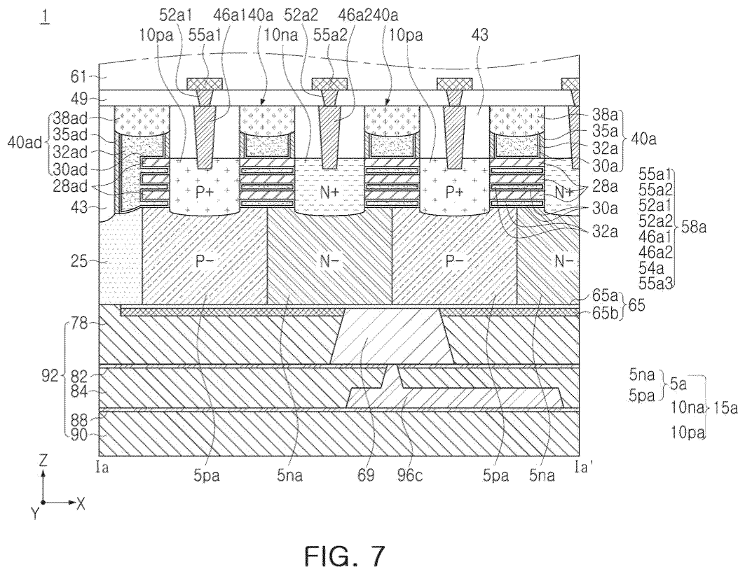

FIG. 7 is a cross-sectional view illustrating a semiconductor device according to one or more embodiments. FIG. 7 shows an area corresponding to an area taken along line Ia-Ia′ of FIG. 2A.

In one or more embodiments, referring to FIG. 7, the passivation structure in FIG. 3A (65 of FIG. 3A) may be replaced with a passivation structure 65 as in FIG. 7. The passivation structure may not include a second insulating passivation layer 65c, but may include a first insulating passivation layer 65a and a conductive passivation layer 65b.

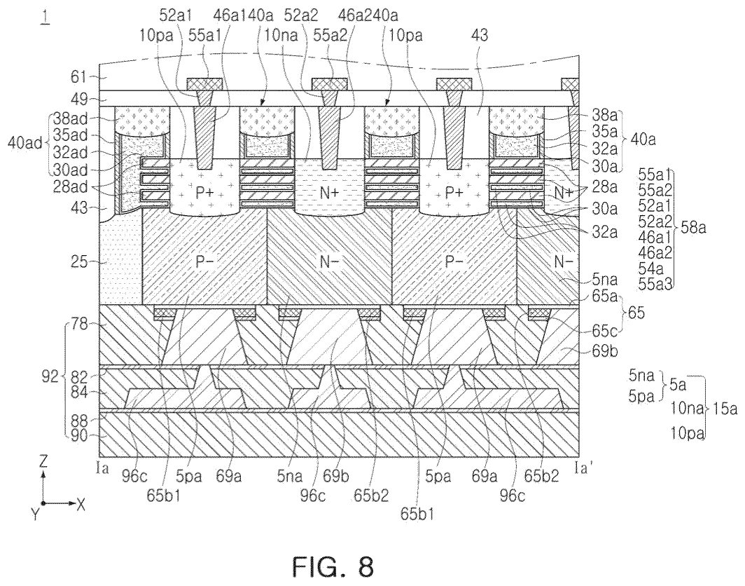

FIG. 8 is a cross-sectional view illustrating a semiconductor device according to one or more embodiments. FIG. 8 shows an area corresponding to an area taken along line Ia-Ia′ of FIG. 2A.

In one or more embodiments, referring to FIG. 8, the backside conductive pattern 69 in FIG. 3A may be replaced with first and second backside conductive patterns 69a and 69b as in FIG. 8. In addition, the conductive passivation layer 65b in FIG. 3A may be replaced with first and second conductive passivation regions 65b1 and 65b2 as in FIG. 8.

For example, the conductive passivation layer 65b may include a first conductive passivation region 65b1 disposed below the first semiconductor region 5pa and a second conductive passivation region 65b2 spaced apart from the first conductive passivation region 65b1 and disposed below the second semiconductor region 5na.

The backside conductive pattern 69 may include a first backside conductive pattern 69a connected to the first conductive passivation region 65b1 and a second backside conductive pattern 69b connected to the second conductive passivation region 65b2.

As described above, the first insulating passivation layer 65a may contact the lower surface of the first semiconductor body 5a and may reduce surface defects, such as dangling bonds, of the lower surface of the first semiconductor body 5a. The conductive passivation layer 65b may be formed of doped pol and thus include a charge. Since the conductive passivation layer 65b is electrically connected to the second backside conductive pattern 69b, the amount of negative charge in the conductive passivation layer 65b may be controlled by controlling the voltage applied.

The negative charge of the conductive passivation layer 65b may have a relatively greater effect on the charge distribution of the second semiconductor region 5na, an n-type, than on the charge distribution of the first semiconductor region 5pa, a P-type.

In one or more embodiments, the first and second backside conductive patterns 69a and 69b may be respectively positioned below the first and second semiconductor regions 5pa and 5na, which are alternately arranged. Accordingly, the negative charges applied to the first backside conductive pattern 69a located under the first semiconductor region 5pa and the second backside conductive pattern 69b located under the second semiconductor region 5na may be set differently. Accordingly, the charge distribution generated by the negative charges of the conductive passivation layer 65b may be controlled differently for the first and second semiconductor regions 5pa and 5na. For example, the amount of charge applied to the first conductive passivation region 65b1 under the first semiconductor region 5pa may be lower than the amount of charge applied to the second conductive passivation region 65b2 under the second semiconductor region 5na. The amount of charge applied is not fixed and may vary depending on the characteristics of the semiconductor regions.

In one or more embodiments, by controlling the amount of negative charge in units of the number of electrons by controlling the voltage applied to the conductive passivation layer 65b, an amount of negative charge suitable for the charge characteristics of the first semiconductor region 5pa and the second semiconductor region 5na may be applied to respective regions.

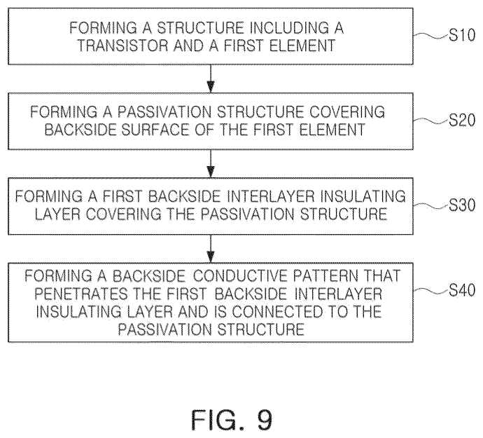

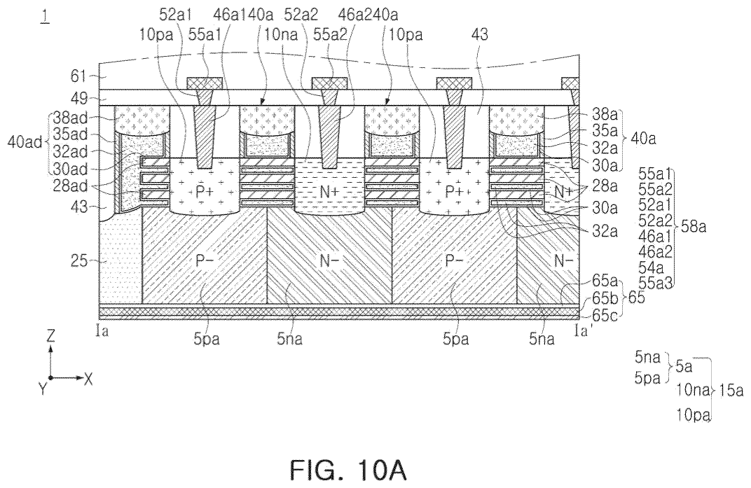

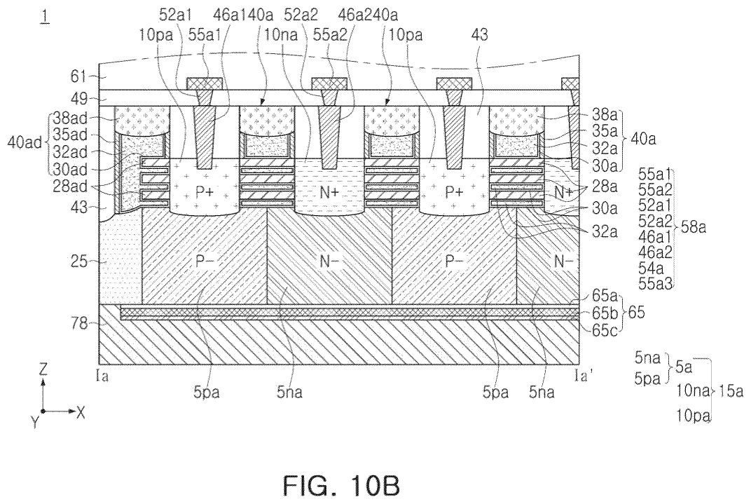

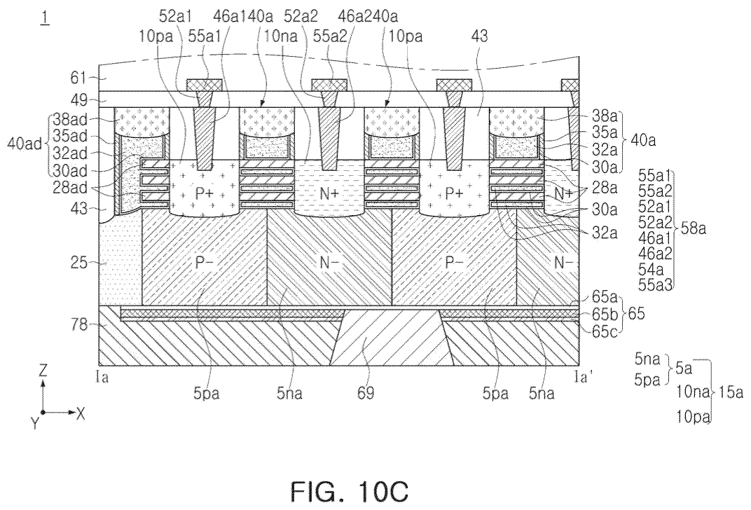

Next, referring to FIG. 9 and FIGS. 10A to 10C, a method of manufacturing a semiconductor device according to one or more embodiments will be described.

FIG. 9 is a flowchart of a method of manufacturing a semiconductor device according to one or more embodiments, and FIGS. 10A to 10C are cross-sectional views of a region taken along the line Ia-Ia′ of FIG. 2A illustrating a method of manufacturing a semiconductor device according to one or more embodiments.

Referring to FIGS. 9 and 10A, a structure including a transistor and a first element may be formed in operation S10. For example, transistors pTR and nTR and a first element 15a different from the transistors pTR and nTR may be formed. The transistors pTR and nTR may be the first and second transistors pTR and nTR described in FIGS. 4, 5A, and 5b, and the first element 15a may be the first element 15a described in FIGS. 2, 3A, 3B, and 3C. Subsequently, a semiconductor process may be performed to form the frontside insulating structure 61 of FIGS. 2 to 5B. Subsequently, a process of reducing the thickness of the semiconductor wafer may be performed to expose the lower surface of the first semiconductor body 5a of the first element 15a. Accordingly, a structure including the first semiconductor body 5a with the exposed lower surface may be formed. The first semiconductor body 5a of the first element 15a may have a thickness of about 50 nm to about 60 nm.

Referring to FIG. 9 and FIG. 10A, a passivation structure 65 covering the backside surface of the first element 15a may be formed in operation S20. For example, a passivation structure 65 contacting the lower surface of the first semiconductor body 5a may be formed.

Forming the passivation structure 65 may include forming a first insulating passivation layer 65a contacting the lower surface of the first semiconductor body 5a of the first element 15a, forming a conductive passivation layer 65b contacting the first insulating passivation layer 65a, and forming a second insulating passivation layer 65c contacting the conductive passivation layer 65b. The first insulating passivation layer 65a and/or the conductive passivation layer 65b may be formed using Atomic Layer Deposition (ALD).

The conductive passivation layer 65b may include a semiconductor material or a conductive material. In one or more embodiments, the conductive passivation layer 65b may include doped polysilicon, and the conductive passivation layer 65b may include boron-doped polysilicon.

The second insulating passivation layer 65c may include a material other than silicon oxide or a low-k dielectric. For example, the second insulating passivation layer 65c may include an insulating material such as SiN, SiBN, SiCN, or AlN.

The first insulating passivation layer 65a may be formed of an oxide layer capable of reducing surface defects, such as dangling bonds, on the lower surface of the first semiconductor body 5a of the first element 15a. The conductive passivation layer 65b may be formed of a conductive material to which a voltage may be applied, such as doped polysilicon.

According to one or more embodiments, the passivation structure 65 may not include a second insulating passivation layer 65c.

Referring to FIGS. 9 and 10B, the passivation structure 65 may be patterned to remove the passivation structure 65 within the transistor area CA. Therefore, the passivation structure 65 may remain within the first element area DA_A.

Subsequently, a first backside interlayer insulating layer 78 covering the passivation structure 65 may be formed in operation S30. The first backside interlayer insulating layer 78 may include silicon oxide or a low-k dielectric having a dielectric constant lower than that of the silicon oxide. Referring to FIG. 3C, the thickness of the first backside interlayer insulating layer 78 may be in a range of about 5 nm to about 15 nm.

Referring to FIGS. 9 and 10C, a backside conductive pattern 69 may be formed in operation S40 that penetrates the first backside interlayer insulating layer 78 and is connected to the passivation structure 65.

The backside conductive pattern 69 may include a conductive material such as copper (Cu), tungsten (W), or molybdenum (Mo).

The backside conductive pattern 69 may penetrate the second insulating passivation layer 65c and contact the conductive passivation layer 65b. In one or more embodiments, a portion of the side surface of the backside conductive pattern 69 may contact the side surface of the conductive passivation layer 65b and the side surface of the second insulating passivation layer 65c. The upper surface of the backside conductive pattern 69 may be coplanar or substantially coplanar with the upper surface of the conductive passivation layer 65b.

According to one or more embodiments, the backside conductive pattern 69 may penetrate the second insulating passivation layer 65c and contact the lower surface of the conductive passivation layer 65b. In particular, the backside conductive pattern 69 may contact the conductive passivation layer 65b and be spaced apart from the first insulating passivation layer 65a.

Referring again to FIGS. 1 to 3C, the backside insulating structure 92 and the first element area backside interconnection structure 96c may be formed. The first element area backside interconnection structure 96c may be electrically connected to the backside conductive pattern 69.

The backside insulating structure 92 may include a first backside interlayer insulating layer 78, a second backside etch stop layer 82, a second backside interlayer insulating layer 84, a third backside etch stop layer 88, and a third backside interlayer insulating layer 90 that are sequentially disposed in a direction away from the passivation structure 65.

As set forth above, according to one or more embodiments, a semiconductor device including a transistor having a three-dimensional structured channel and a device including semiconductor regions forming a PN junction may be provided.

According to one or more embodiments, a frontside conductive structure on the transistor and a backside interconnection structure below the transistor may be provided. The frontside conductive structure and backside interconnection structure may significantly reduce power and signal paths, thereby improving the performance of semiconductor device.

According to one or more embodiments, a passivation structure may be provided, which contacts a lower surface of a semiconductor body including the semiconductor regions of the device, thereby preventing or reducing surface defects of the semiconductor body. This passivation structure may improve the performance of the device.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a transistor;
a first element spaced apart from the transistor in a first direction;
a backside insulating structure below the transistor and the first element in a second direction that is perpendicular to the first direction;
a passivation structure between the first element and the backside insulating structure; and
a backside conductive pattern disposed in the backside insulating structure and connected to the passivation structure,
wherein the first element comprises a first semiconductor region having a first conductivity type and a second semiconductor region having a second conductivity type and that forms a PN junction with the first semiconductor region,
wherein the passivation structure comprises a first insulating passivation layer contacting a lower surface of the first element and a conductive passivation layer below the first insulating passivation layer, and
wherein the backside conductive pattern is connected to the conductive passivation layer.

2. The semiconductor device of claim 1, wherein an upper surface of the backside conductive pattern contacts the first insulating passivation layer.

3. The semiconductor device of claim 1, wherein a length of the backside conductive pattern is in a range of 15 nm to 25 nm in the second direction.

4. The semiconductor device of claim 1, wherein a width of the backside conductive pattern is in a range of 45 nm to 55 nm.

5. The semiconductor device of claim 1, wherein the backside insulating structure comprises a first backside interlayer insulating layer, and
wherein a lower surface of the backside conductive pattern and a lower surface of the first backside interlayer insulating layer are substantially coplanar.

6. The semiconductor device of claim 1, wherein the backside conductive pattern contacts the conductive passivation layer and is spaced apart from the first insulating passivation layer.

7. The semiconductor device of claim 1, wherein a thickness of the conductive passivation layer is in a range of 4.5 nm to 5.5 nm in the second direction.

8. The semiconductor device of claim 1, wherein at least one of the first semiconductor region and the second semiconductor region has a thickness in a range of 50 nm to 60 nm in the second direction.

9. The semiconductor device of claim 1, wherein the first insulating passivation layer comprises silicon oxide, silicon nitride, or silicon oxynitride.

10. The semiconductor device of claim 1, wherein the conductive passivation layer comprises doped polysilicon.

11. The semiconductor device of claim 1, wherein the passivation structure further comprises a second insulating passivation layer between the backside insulating structure and the conductive passivation layer, and
wherein the backside conductive pattern penetrates the second insulating passivation layer and contacts the conductive passivation layer.

12. The semiconductor device of claim 1, wherein the conductive passivation layer does not overlap the transistor in the second direction.

13. A semiconductor device comprising:
a transistor;
a first element spaced apart from the transistor in a first direction, the first element comprising a semiconductor body comprising a first semiconductor region having a P-type conductivity type and a second semiconductor region having an N-type conductivity type;
a backside insulating structure below the transistor and the first element in a second direction that is perpendicular to the first direction;
a passivation structure between the first element and the backside insulating structure; and
a backside conductive pattern disposed in the backside insulating structure and connected to the passivation structure,
wherein the passivation structure comprises:
a first insulating passivation layer contacting the semiconductor body; and
a conductive passivation layer below the first insulating passivation layer in the second direction, and
wherein the backside conductive pattern is connected to the conductive passivation layer and is spaced apart from the first semiconductor region and the second semiconductor region in the second direction.

14. The semiconductor device of claim 13, wherein the conductive passivation layer comprises doped polysilicon.

15. The semiconductor device of claim 13, wherein the conductive passivation layer comprises:
a first conductive passivation region below the first semiconductor region in the second direction; and
a second conductive passivation region spaced apart from the first conductive passivation region in the first direction and disposed below the second semiconductor region in the second direction, and
wherein the backside conductive pattern comprises:
a first backside conductive pattern connected to the first conductive passivation region; and
a second backside conductive pattern connected to the second conductive passivation region.

16. The semiconductor device of claim 13, wherein the first element further comprises:
a first semiconductor pattern on the first semiconductor region of the semiconductor body; and
a second semiconductor pattern on the second semiconductor region of the semiconductor body,
wherein the first semiconductor pattern has a P-type conductivity and has an impurity concentration higher than an impurity concentration of the first semiconductor region, and
wherein the second semiconductor pattern has an N-type conductivity and has an impurity concentration higher than an impurity concentration of the second semiconductor region.

17. The semiconductor device of claim 13, wherein the conductive passivation layer does not overlap the transistor in the second direction.

18. A semiconductor device comprising:
a transistor;
a first element spaced apart from the transistor in a first direction;
a backside insulating structure below the transistor and the first element in a second direction that is perpendicular to the first direction;
a conductive passivation layer between the first element and the backside insulating structure and not between the transistor and the backside insulating structure;
an insulating passivation layer between the first element and the conductive passivation layer; and
a backside conductive pattern connected to the conductive passivation layer,
wherein the first element comprises a first semiconductor region and a second semiconductor region that forms a PN junction, and
wherein the conductive passivation layer comprises doped polysilicon.

19. The semiconductor device of claim 18, wherein the insulating passivation layer contacts at least one of the first semiconductor region and the second semiconductor region.

20. The semiconductor device of claim 18, wherein, in the second direction, a thickness of the conductive passivation layer is greater than a thickness of the insulating passivation layer.
